(19) United States
(12) Patent Application Publication
(10) Pub. No.: US 2021/0135624 A1
(43) Pub. Date: May 6, 2021

(54) CONNECTOR

(71) Applicant: INDUSTRIAL TECHNOLOGY RESEARCH INSTITUTE, Hsinchu (TW)

(72) Inventors: Ren-Chin Shr, Hsinchu (TW); Jhong-Yuan Wang, Hsinchu (TW); Chin Lien, Hsinchu (TW); Kuan-Wu Lu, Hsinchu (TW)

(21) Appl. No.: 16/728,058

(22) Filed: Dec. 27, 2019

Related U.S. Application Data
(60) Provisional application No. 62/928,413, filed on Oct. 31, 2019.

(51) Int. Cl. H02S 50/10; G01R 31/26; H02S 40/34; G01R 31/36

(52) U.S. Cl. CPC H02S 50/10; G01R 31/36; H02S 40/34; G01R 31/2603

(57) ABSTRACT

Provided a connector including a first female connector and a first male connector. The first female connector includes a first male sleeve, and a probe is disposed on the first male sleeve. The first male connector includes a first female sleeve, in which an elastic structure is disposed in the first female sleeve. The probe passes through a hole on the first male sleeve and is electrically connected to a second female sleeve in a second male connector. The elastic structure is electrically connected to a second male sleeve in a second female connector.

### BACKGROUND

### 1. Technical Field

The present disclosure relates to a connector, and, more particularly, to a connector of an electrical measurement device using a four-wire measurement method.

### 2. Description of the Prior Art

When the resistance value of the object to be measured is much smaller than the resistance value of the wire (e.g., the resistance value of the object to be measured is about 1/10 of the resistance value of the wire), the four-wire measurement method can avoid the influence of the resistance value of the wire comparing with the two-wire measurement method. Therefore, four-wire I-V measurement equipment is often used to measure the electrical properties of solar power modules.

FIG. 1 is a conventional electrical measurement equipment of a solar power module. The positive electrode of the solar power module is electrically connected to the male connector of the MC4 connector, and the negative electrode is electrically connected to the female connector of the MC4 connector. MC4 connectors are prone to aging due to frequent plugging and unplugging. FIG. 2 shows the electrical curve of the solar power module measured when the MC4 connector is aged. The solid curve indicates the correct I-V curve, and the dashed curve indicates the I-V curve measured when the MC4 connector is aged. As can be seen from FIG. 2, the maximum power point Pmax changes with the aging of the MC4 connector. Therefore, measurement errors also occur.

Referring to FIG. 1, the male and female connectors of the MC4 connector are electrically connected to the female and male connectors of the MC4 connector, respectively. The female connector and the male connector of the MC4 connector are electrically connected to a terminal block (TB) via a divided wire, respectively. The four terminals of the terminal block are electrically connected to the positive and negative terminals of the voltage and the positive and negative terminals of the current of the four-wire electrical measuring equipment, respectively. R1 and R1′ are the resistance between the male connector and the female connector of the MC4 connector, R3 and R3′ are the resistance of the terminal block, R2 and R2′ are the resistance of the wire between the connector and the terminal block, and R is the resistance to be measured of the solar power module.

FIG. 3 is an equivalent circuit diagram of the electrical measuring equipment shown in FIG. 1. According to this arrangement, the measured resistance is R1+R2+R+R1′+R2′ instead of R. When the MC4 connector ages, it will cause measurement errors.

Therefore, there is a need for a connector that can accurately measure the resistance to be measured of a solar power module via a four-wire measurement method to avoid errors caused by aging of the connector.

### SUMMARY

According to an embodiment disclosed by the present disclosure, the present disclosure provides a connector, including: a first female connector and a first male connector. The first female connector includes a first male sleeve, and a probe is disposed on the first male sleeve. The first male connector includes a first female sleeve, in which an elastic structure is disposed in the first female sleeve. The probe passes through a hole on the first male sleeve and is electrically connected to a second female sleeve in a second male connector. The elastic structure is electrically connected to a second male sleeve in a second female connector.

According to the embodiment disclosed by the present disclosure, the present disclosure provides a connector, in which the probe is electrically connected to a voltage positive electrode of an electrical measurement device, and the elastic structure is electrically connected to a voltage negative electrode of the electrical measurement device.

According to the embodiment disclosed by the present disclosure, the present disclosure provides a connector, in which the first male sleeve is electrically connected to a current positive electrode of the electrical measurement device, and the first female sleeve is electrically connected to a current negative electrode of the electrical measurement device.

According to the embodiment disclosed by the present disclosure, the present disclosure provides a connector, in which the second female sleeve is electrically connected to a positive electrode of a test object, and the second male sleeve is electrically connected to a negative electrode of the test object.

### BRIEF DESCRIPTION OF THE DRAWINGS

The present disclosure can be more fully understood by reading the subsequent detailed description and examples with references made to the accompanying drawings, wherein:

FIG. 1 is a conventional electrical measurement equipment of a solar power module;

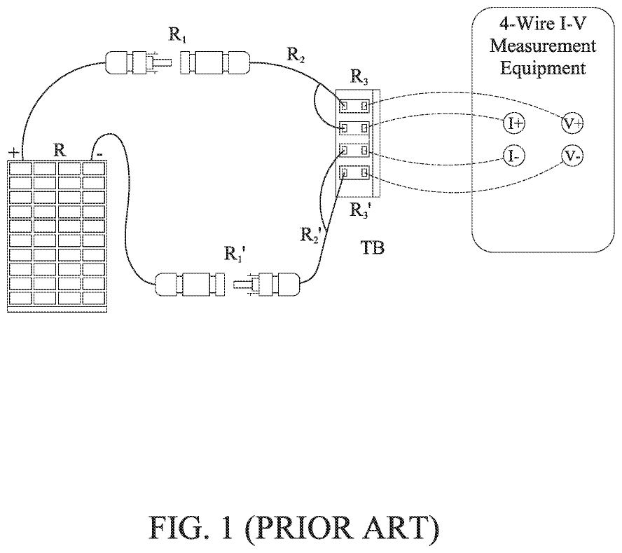

FIG. 2 shows the I-V curve of the solar power module measured when the MC4 connector is aged;

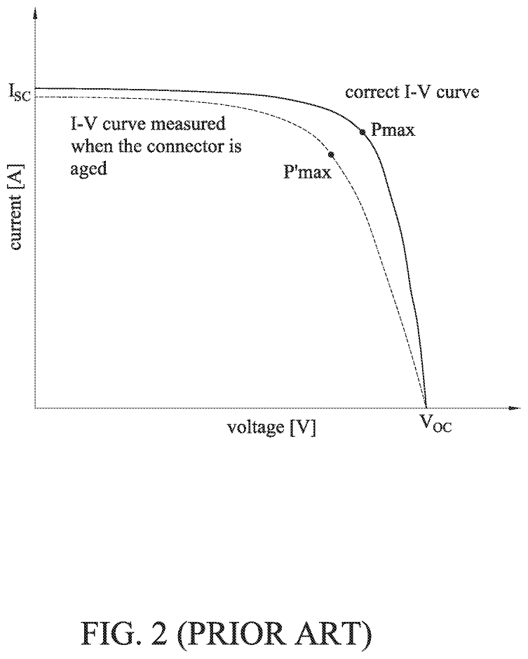

FIG. 3 is an equivalent circuit diagram of the electrical measurement equipment shown in FIG. 1;

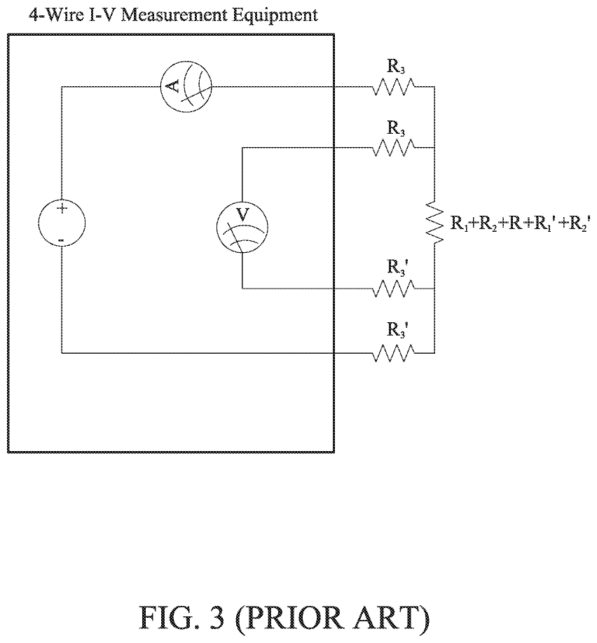

FIG. 4 is a diagram of a connector according to an embodiment of the present disclosure;

FIG. 5 is an equivalent circuit diagram using the connector shown in FIG. 4; and

FIG. 6 is an I-V curve measured using the connector according to an embodiment of the present disclosure.

### DETAILED DESCRIPTION

Technical terms of the present disclosure are based on general definition in the technical field of the present disclosure. If the present disclosure describes or explains one or some terms, definition of the terms is based on the description or explanation of the present disclosure. Each of the disclosed embodiments has one or more technical features. In possible implementation, a person skilled in the art would selectively implement all or some technical features of any embodiment of the present disclosure or selectively combine all or some technical features of the embodiments of the present disclosure.

In each of the following embodiments, the same reference number represents the same or similar element or component.

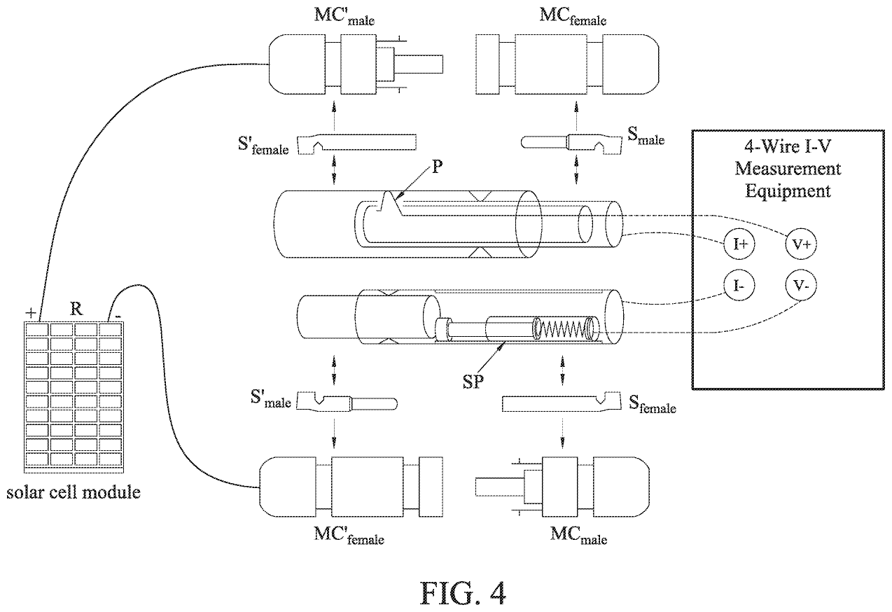

Referring to FIG. 4, an embodiment of the present disclosure is disclosed. This embodiment provides a connector including a first female connector MCfemale and a first male connector MCmale. The first female connector MCfemale includes: a first male sleeve Smale. The first male connector MCmale includes: a first female sleeve Sfemale.

A probe P is provided in the first male sleeve Smale, and an elastic structure SP is provided in the first female sleeve Sfemale. The probe P penetrates a hole on the first male sleeve Smale and is electrically connected to a second female sleeve S′female in a second male connector MC′male. The elastic structure SP is electrically connected to the second male sleeve S′male in the second female connector MC′female.

According to the embodiment disclosed by the present disclosure, the embodiment provides a connector, in which the probe P is electrically connected to a voltage positive electrode V+ of the 4-wire I-V measurement equipment, and the elastic structure SP is electrically connected to a voltage negative electrode V− of the 4-wire I-V measurement equipment.

According to the embodiment disclosed by the present disclosure, the embodiment provides a connector, in which the first male sleeve Smale is electrically connected to a current positive electrode I+ of the 4-wire I-V measurement equipment, and the first female sleeve Sfemale is electrically connected to a current negative electrode I− of the 4-wire I-V measurement equipment.

According to the embodiment disclosed by the present disclosure, the embodiment provides a connector, in which the second female sleeve S′female in the second male connector MC′male is electrically connected to a positive electrode of a test object (i.e., the solar power module), and the second male sleeve Smale in the second female connector MC′ female is electrically connected to a negative electrode of the test object.

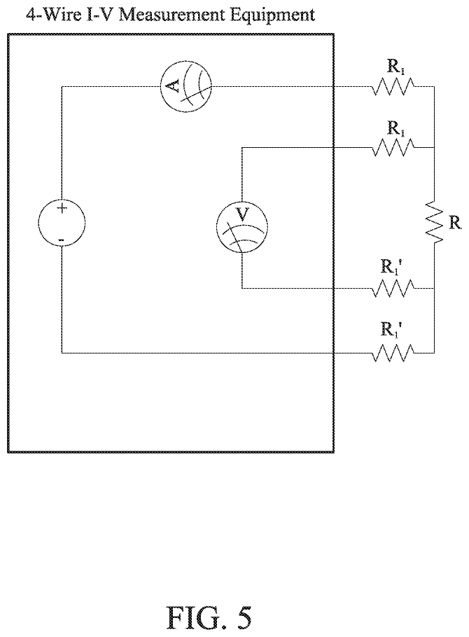

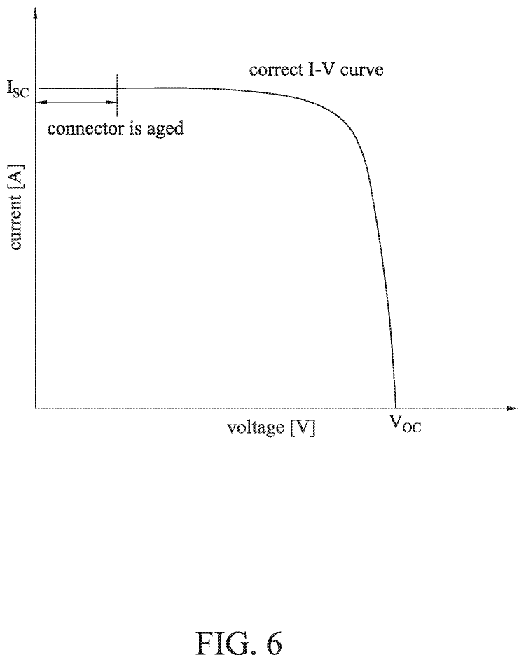

FIG. 5 is an equivalent circuit diagram using the connector shown in FIG. 4. With the connector provided by the present disclosure, the measured resistance of the solar power generation module is R. FIG. 6 is an I-V curve measured using the connector disclosed in the embodiment of the present disclosure. When the connector is aged, the connector disclosed in the present disclosure will cause the I-V curve to generate a measurement window in the section where the voltage is very low; that is, when the voltage is very low, the short-circuit current will not be measured. However, the overall I-V curve does not change, so the correct I-V curve can still be measured.

While the present disclosure has been described by way of examples and in terms of the embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A connector, comprising:
a first female connector, comprising:
a first male sleeve with a probe disposed in the first male sleeve; and
a first male connector, comprising:
a first female sleeve with an elastic structure disposed in the first female sleeve, wherein the probe passes through a hole on the first male sleeve and is electrically connected to a second female sleeve in a second male connector, and the elastic structure is electrically connected to a second male sleeve in a second female connector.

2. The connector of claim 1, wherein the probe is electrically connected to a voltage positive electrode of an electrical measurement device, and the elastic structure is electrically connected to a voltage negative electrode of the electrical measurement device.

3. The connector of claim 2, wherein the first male sleeve is electrically connected to a current positive electrode of the electrical measurement device, and the first female sleeve is electrically connected to a current negative electrode of the electrical measurement device.

4. The connector of claim 1, wherein the second female sleeve is electrically connected to a positive electrode of a test object, and the second male sleeve is electrically connected to a negative electrode of the test object.
